(19) United States
(12) Patent Application Publication
(10) Pub. No.: US 2013/0032885 A1
(43) Pub. Date: Feb. 7, 2013

(54) AREA EFFICIENT GRIDDED POLYSILICON LAYOUTS

(71) Applicants: Chethan Swamynathan, Bangalore (IN); Jay Madhukar Shah, Bangalore (IN); Vijayalakshmi Ranganna, Bangalore (IN); Foua Vang, San Diego, CA (US); Pratyush Kamal, San Diego, CA (US); Prayag B. Patel, San Diego, CA (US)

(72) Inventors: Chethan Swamynathan, Bangalore (IN); Jay Madhukar Shah, Bangalore (IN); Vijayalakshmi Ranganna, Bangalore (IN); Foua Vang, San Diego, CA (US); Pratyush Kamal, San Diego, CA (US); Prayag B. Patel, San Diego, CA (US)

(73) Assignee: QUALCOMM INCORPORATED, San Diego, CA (US)

(21) Appl. No.: 13/197,195

(22) Filed: Aug. 3, 2011

(51) Int. Cl. H01L 27/088; H01L 21/02; H01L 21/28

(52) U.S. Cl. 257/368; 438/585; 29/25.01; 257/E27.06; 257/E21.19

(57) ABSTRACT

Gridded polysilicon semiconductor layouts implement double poly patterning to cut polylines of the layout into polyline segments. Devices are arranged on the polyline segments of a common polyline to reduce the area used to implement a circuit structure relative to conventional gridded polysilicon layout. Stacking of PMOS and NMOS devices is enabled by using double poly patterning to implement additional cuts which form additional polyline segments. Metal layer routing may connect nodes of separate polyline segments.

### FIELD OF DISCLOSURE

The present disclosure relates to manufacturing semiconductor devices, and, more specifically, to manufacturing devices having a gridded polysilicon layout.

### BACKGROUND

In semiconductor design, standard cell methodology involves designing integrated circuits having various functionalities using standard components and interconnect structures. These activities are facilitated within a computer aided design environment. Standard ceil methodology uses abstraction in which low level integrated circuit synthesis is replaced by a more abstract, higher-level functional representation. Cell-based methodologies allow designers to focus on the high-level aspect of design. A standard cell can include a group of transistor structures, passive structures, and interconnect structures with atomic functions such as logic functions, storage functions or the like. When the cell design is completed, fabrication may be performed to carry out the physical implementation.

Polylines are graphical objects offered as part of conventional computer aided design packages. Polylines during the design stage correspond to polysilicon gates patterned onto semiconductors. In a gridded polysilicon layout, the polylines are regularly spaced relative to each other, i.e., the polylines have a regular pitch.

Devices, such as transistors, include these regularly spaced polysilicon gates in addition to the standard diffusion areas and contacts (i.e., gate connections). Due to design rules, etching a polyline to create two polyline segments would result in transistors that would be smaller than generally desired. For example transistors could be too small to be allowed by the design rules of 28 nm technology. Thus, conventional layouts involving devices without a common gate voltage occupy two polylines.

It would be desirable to reduce the area for standard sized devices not having a common gate voltage, while still complying with design rules.

### SUMMARY

Embodiments of the present disclosure include a semiconductor apparatus having a polysilicon layer patterned a substrate in a grid. The polysilicon layer grid pattern includes a number of evenly spaced polysilicon gates. At least one of the polysilicon gates includes a first polysilicon gate segment electrically separated from a second polysilicon gate segment so that the first and second polysilicon gate segments are configured to receive different input signals. The embodiments also include a first diffusion region in the substrate having a portion of the first diffusion region being provided under the first polysilicon gate segment and a second diffusion region in the substrate having a portion of the second diffusion region being provided under the second polysilicon gate segment. According to aspects of the present disclosure, the first polysilicon gate segment and the second polysilicon gate segment are separated as a result of double poly patterning.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The accompanying drawings are presented to aid in the description of embodiments. The drawings are provided solely for illustration of the embodiments and not limitation thereof.

FIG. 1 is a diagram illustrating a circuit that may implemented in semiconductor apparatus according to examples of the present disclosure.

FIG. 2 is a diagram showing a conventional gridded polysilicon layout for implementing the circuitry shown in FIG. 1.

FIG. 3 is a diagram showing a gridded polysilicon layout for implementing the circuitry shown in FIG. 1 according to an example of the present disclosure.

FIG. 4A is a diagram showing a conventional gridded polysilicon layout for implementing a tri-state inverter/transmission gate structure.

FIG. 4B is a diagram showing a gridded polysilicon layout for implementing a tri-state inverter/transmission gate structure according to an example of the present disclosure.

FIG. 5A is a diagram showing a conventional gridded polysilicon layout for implementing series and parallel devices.

FIG. 5B is a diagram showing a gridded polysilicon layout for implementing series and parallel devices according to an example of the present disclosure.

FIG. 6A is a diagram showing a conventional gridded polysilicon layout for implementing stacked n-channel metal oxide semiconductor (NMOS) and p-channel metal oxide semiconductor (PMOS) devices.

FIG. 6B is a diagram showing a gridded polysilicon layout for implementing stacked NMOS and PMOS devices according to an example of the present disclosure.

FIG. 7 is a process flow diagram showing a method of arranging a gridded polysilicon layout according to an example of the present disclosure.

FIG. 8 is a block diagram showing an exemplary wireless communication system in which an embodiment of the disclosure may be advantageously employed.

FIG. 9 is a block diagram illustrating a design workstation used for circuit, layout, and logic design of a semiconductor component, such as a high voltage tolerant differential receiver circuitry according to the aspects of the present disclosure.

### DETAILED DESCRIPTION

Aspects are disclosed in the following description and related drawings directed to specific embodiments. Alternate embodiments may be devised without departing from the scope of the disclosure. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments of the disclosure” does not require that all embodiments include the discussed feature, advantage or mode of operation.

The terminology used herein is for the purpose of describing particular embodiments only and is not intended to be limiting of embodiments of the disclosure. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated, features, integers, steps, operations, elements, and/or components, but do not preclude the presence or addition of one or more other features, integers, steps, operations, elements, components, and/or groups thereof.

In connection with the present disclosure, the term “polyline” may refer to a graphical object available in a computer aided design (CAD) system for representing lines (open polyline) and/or for polygonal objects such as transistor gates, circuit traces and the like (closed polyline). The phrase “double polyline patterning” refers to the use of successive polylines to specify corresponding successive patterning steps during fabrication to form irregular features or features having a finer resolution than normally possible with the current fabrication or lithography scale. The double patterning technique is a relatively new process, used at the 28 nm node. Various techniques can be appreciated as techniques for specifying the cell libraries and generating output file formats as described herein including but not limited to freeware software design systems such as Magic design system, Electric VLSI design system, and commercially available systems such as the family of IC design systems offered by Mentor Graphics, Inc. such as Design Architect IC, IC Station, Quicksim II, Mach TA/Accusim II, systems offered by Cadence® Design Systems such as Composer, Verilog-XL, Virtuoso, Silicon Ensemble, Spectre and systems offered by Tanner Research, Inc. such as S-Edit, L-Edit, LVS, T-Spice.

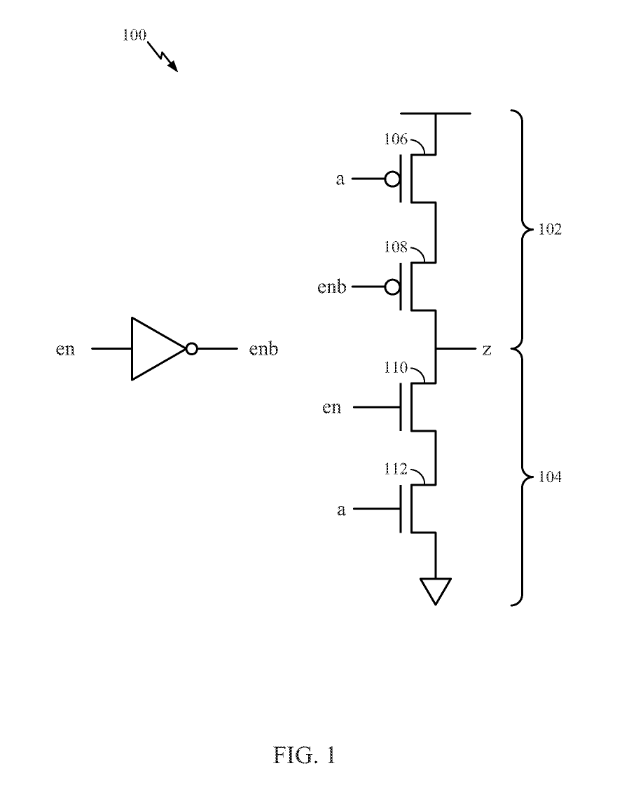

FIG. 1 is a diagram illustrating an example circuit 100 which may be fabricated using a gridded polysilicon process based upon a standard cell library design. The example circuit 100 is a tri-state inverter having a PMOS area 102 including PMOS transistors 106, 108 and an NMOS area 104 including NMOS transistors 110, 112. PMOS transistor 106 and NMOS transistor 112 share a common gate voltage, labeled “a”. PMOS transistor 108 is controlled by an input signal “enb”. NMOS transistor 110 is controlled by an input signal “en”. Thus, the circuit 100 has three different gate voltages for four different devices.

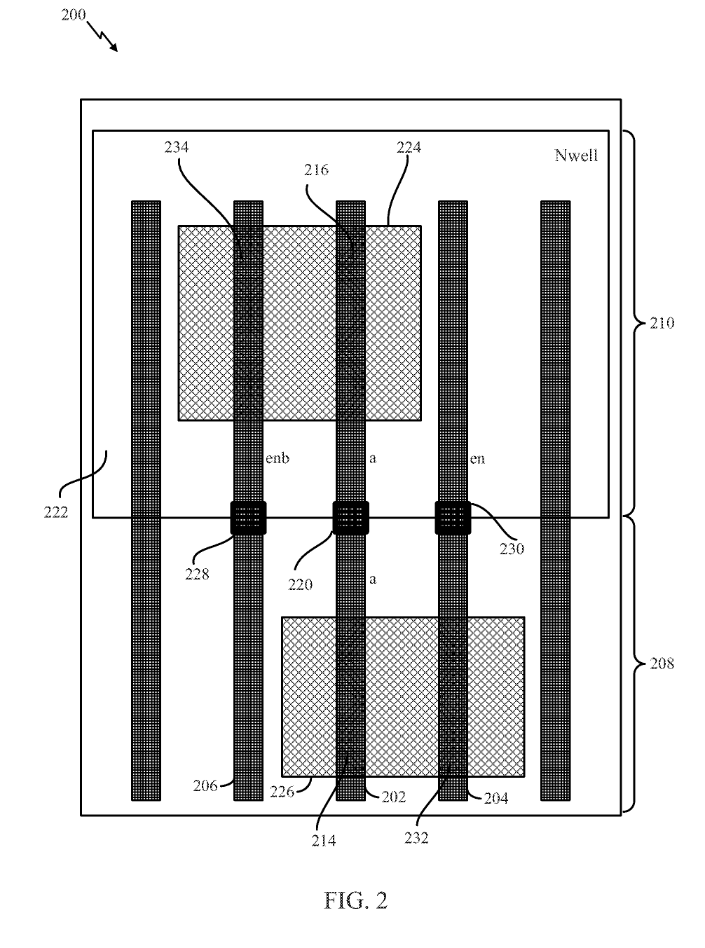

Gridded polysilicon layout designs have the polysilicon gates of transistors at constant intervals (polysilicon pitch) thereby restricting horizontal direction usage of polysilicon. A conventional way of implementing the circuit 100 in a gridded polysilicon layout is described with reference to FIG. 2. This layout uses a single common polyline 202 for the gate voltage “a.” That is, a PMOS transistor 212 and an NMOS transistor 214 each have a gate 216 coupled to a contact 220 that receives the voltage “a”. It is noted that the section 222 designates an N well, although the present disclosure also contemplates an N-type substrate with a P well. In FIG. 2, the regions 224, 226 designate diffusion regions, and each transistor is located at the intersection of a diffusion region and a gate.

Separate polylines 204, 206 correspond to gates having contacts 228, 230 receiving input signals “en” for the NMOS transistor 232 located in the NMOS area 208 of the layout and “enb” for the PMOS transistor 234 located in the PMOS area 210 of the layout. Thus, a conventional gridded polysilicon layout of the circuit 100 uses three polylines 202, 204, 206 and therefore occupies a width of three gates. Such gridded polysilicon layouts result in a significant area increase of about 33% for tri-State (TS) inverter circuitry as compared to a non-gridded polysilicon layout (i.e. a layout without a constant polysilicon pitch).

Transmission gate (TG) circuitry, like tri-state inverter circuitry, also includes different input signals connected to PMOS and NMOS devices and can be implemented in a gridded polysilicon layout using three polylines. Such implementation of transmission gate circuitry also results in a significant area increase of about 33% compared to non-gridded poly silicon layout.

According to one aspect of the present disclosure, circuitry such as the tri-state inverter circuit 100 may be implemented in a gridded polysilicon layout occupying the same area as a non-gridded polysilicon layout.

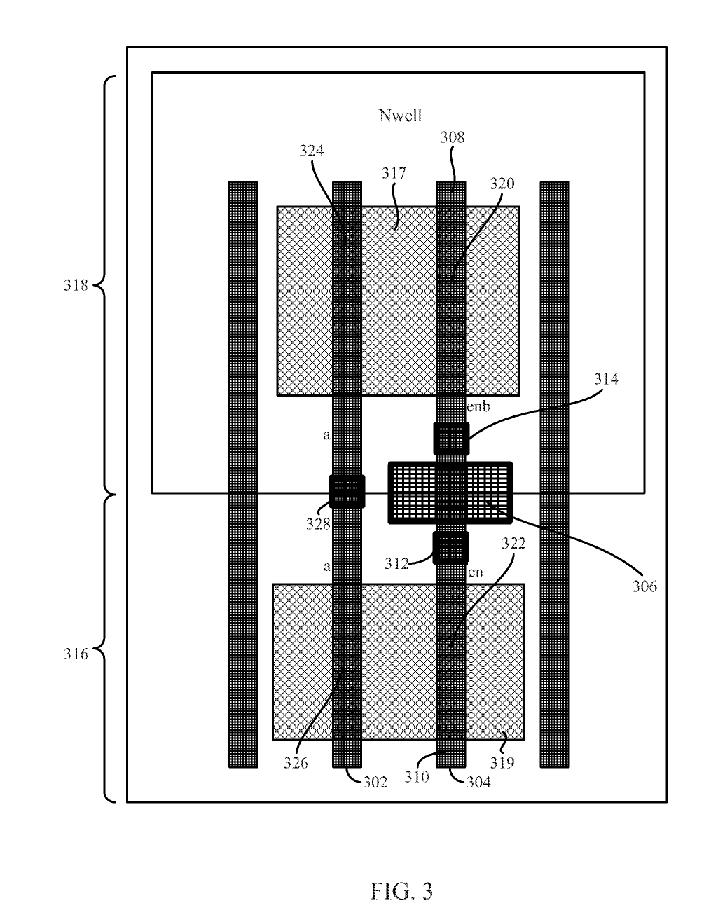

Referring to FIG. 3 a single common polyline 302 is used for the common node “a.” A common polyline 304 is also used for different input signals “en” located in an NMOS area 316 of the layout and “enb” located in a PMOS area 318 of the layout. A double poly patterning mask layer 306 (also referred to as a cut poly layer) occurs between the input nodes “en” and “enb” to divide the polyline 304 into two separate polyline segments 308, 310. A result of this double poly patterning mask layer 306 is a layout having a width of two gates to implement the tri-state inverter even though the tri-state inverter includes three different input nodes.

The double poly patterning enables manufacturing of a semiconductor apparatus including transistors arranged on a polyline grid having evenly spaced polylines with reduced area. A first polyline 304 is divided to include a first polyline segment 308 and a second polyline segment 310. As noted above, the separation results from a double poly patterning 306 in the first polyline 304. A first PMOS transistor 320 is configured on the first polyline segment 308 and a second transistor (NMOS) 322 is configured on the second polyline segment 310. The cut poly layer 306 is configured for causing the first cut between a gate contact 312 of the first transistor 320 and a gate contact 314 of the second transistor 322.

The semiconductor apparatus shown in FIG. 3 also includes a third transistor (PMOS) 324 and a fourth transistor 326 (NMOS) configured on a second polyline 302. The first and third transistors 320, 324 each include a portion of a first diffusion area (P-type) 317. The second and fourth transistors 322, 326 each include a portion of a second diffusion area 319 (N-type). The third and fourth transistors 324, 326 share a common gate contact 328 and thus share a common gate voltage.

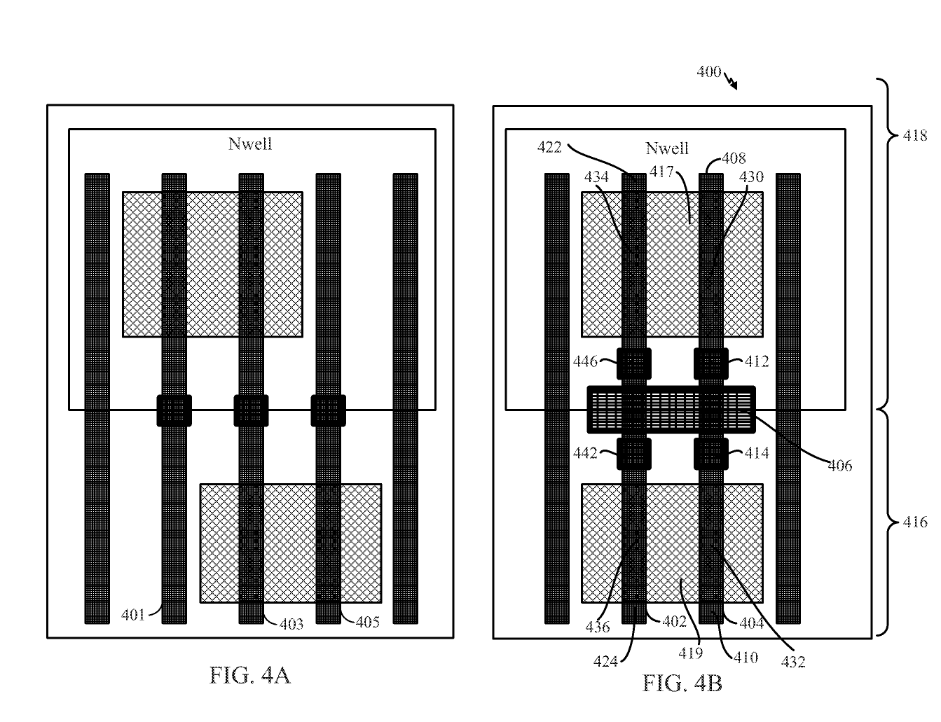

Double poly patterning may also be used according to aspects of the present disclosure in a gridded poly silicon layout wherever cross-connection of gates occurs, for example in a tri-state inverter or transmission gate. For example, FIG. 4A shows a conventional method of implementing a tri-state inverter/transmission gate structure in a gridded polysilicon layout using three polylines 401, 403, 405 as previously described with reference to FIG. 2. An aspect of the present disclosure described with reference to FIG. 4B provides another gridded polysilicon layout 400 for implementing a tri-state inverter/transmission gate structure that employs only two polylines.

A layout for a structure with a double poly patterning mask layer and cross connected gates is similar to the layout described with reference to FIG. 3. A first polyline 404 includes a first polyline segment 408 and a second polyline segment 410 separated as a result of a double poly patterning mask layer 406. A first transistor (PMOS) 430 is configured on the first polyline segment 408 and a second transistor (NMOS 432) is configured on the second polyline segment 410. The cut poly layer 406 is configured for dividing the first polyline 404 between a gate contact 412 of the first transistor 430 and a gate contact 414 of the second transistor 432. Thus, these gate contacts 412, 414 can be provided with different input signals “a,” and “en.”

A third transistor (PMOS) 434 and fourth transistor (NMOS) 436 are configured on a second polyline 402. The first transistor and the third transistors 430, 434 in a PMOS area 418 of the layout each include a portion of a first diffusion area 417. The second transistor 432 and the fourth transistor 436 in an NMOS area 416 each include a portion of a second diffusion area 419.

In this layout 400, the second polyline 402 is divided into a third polyline segment 422 and a fourth polyline segment 424 by the double poly patterning mask layer 406. The third transistor 434 is configured on the third polyline segment 422 adjacent to the first transistor, and the fourth transistor is configured on the fourth polyline segment 424 adjacent to the second transistor. In this design, the cut poly layer 406 is configured for dividing both the first and second poly lines 402, 404, enabling the fabrication of four transistors having at least one of the diagonally opposite pairs of gate contacts configured at the same potential. In the example of FIG. 4B, the gate contacts 412, 442 of the transistors 430, 436 coupled to node “a” are diagonally opposite. A connection between the diagonally opposed gates may be fabricated with conductive (e.g., metal) layers, not shown, for example. The other gate contacts 414, 446 of the transistors 432, 434 are coupled to nodes “en” and “enb,” respectively.

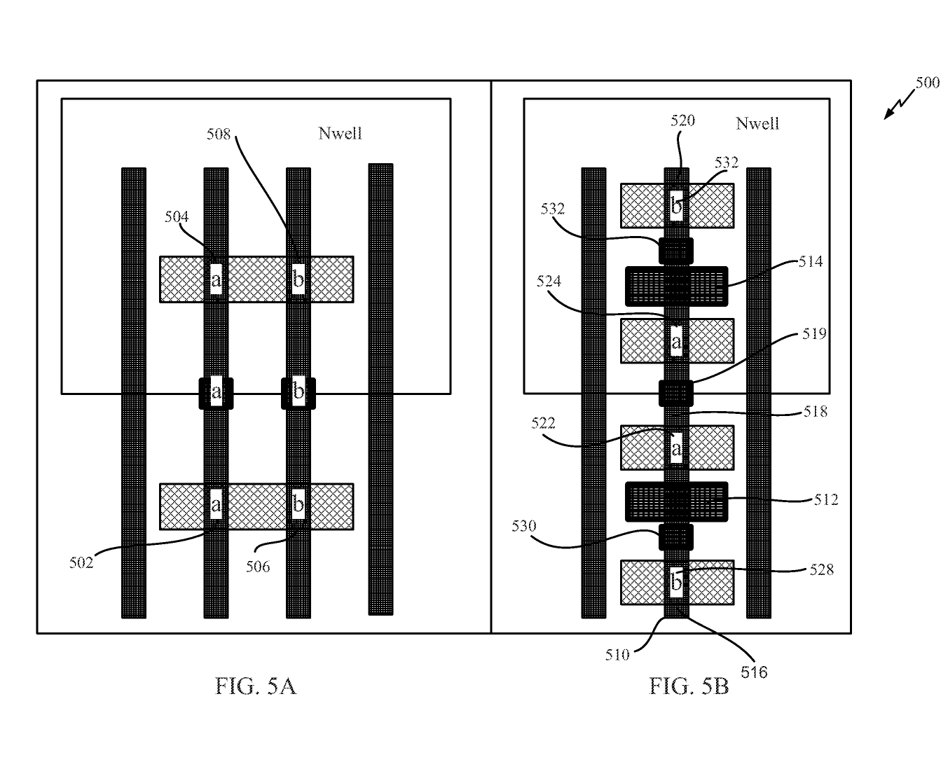

Double poly patterning can also be used to design stacked PMOS and NMOS devices, to further reduce area of a layout. Stacking of PMOS and NMOS devices may occur in lower drive cells in high performance architecture having more than a usual height, for example. FIG. 5A shows a conventional layout for implementing series and parallel stacked PMOS and NMOS devices using gridded poly patterning. The conventional layout occupies two polylines to implement four devices in which a first NMOS device 502 shares a common gate potential “a” with a first PMOS device 504. A second NMOS device 506 shares a common gate potential “b” with a second PMOS device 508.

FIG. 5B shows a double poly patterned design 500 according to an aspect of the disclosure in which stacking of PMOS and NMOS devices is implemented in a gridded polysilicon layout on a single polyline 510. A first double poly patterning mask layer 512 separates the single polyline 510 into a first polyline segment 516 and a second polyline segment 518. A second double poly patterning mask layer 514 separates a third polyline segment 520 of the polyline 510 from the second polyline segment 518.

A first NMOS device 522 is formed in a diffusion area in an NMOS portion of the second polyline segment 518 and a first PMOS device 524 is formed in a diffusion area in a PMOS portion of the second polyline segment 518. A common gate contact 519 is shared between the first NMOS device 522 and the first PMOS device 524.

A second NMOS device 532 is formed in a diffusion area on the third polyline segment 520 and a second PMOS device 528 is formed in a diffusion area on the first polyline segment 516. A gate contact 530 on the first polyline segment 516 may be coupled to a gate contact 532 on the third polyline segment 520 via conductive (e.g., metal) layers, not shown, for example.

As can be seen, the present disclosure provides a stacked PMOS NMOS design occupying only a single polyline. Thus, the overall area consumed by this design is 50% less than the area consumed by the conventional design of FIG. 5A.

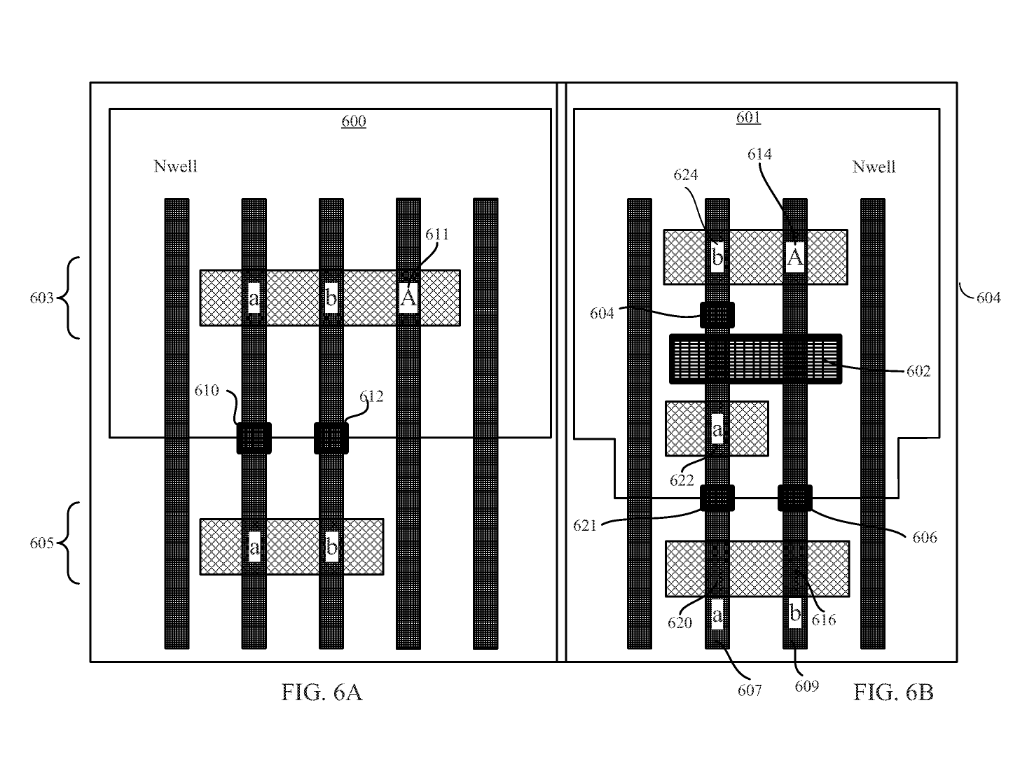

Double poly patterning can also be used according to aspects of the present disclosure to stack PMOS and/or NMOS devices sharing common gate potentials in combination with another device having a different gate potential. In this aspect, the area savings resulting from the double poly patterning may be utilized for the other device(s), further reducing area of the overall layout. FIG. 6A shows, a conventional gridded polysilicon layout 600 implementing PMOS devices 603 and NMOS devices 605 in which common gate contacts 610, 612 are shared between certain pairs of PMOS and NMOS devices. Another device 611 having its own gate input is also provided within the layout. The layout occupies the area of three polylines.

FIG. 6B shows a gridded polysilicon layout 601 according to an aspect of the present disclosure in which double poly patterning reduces the layout area of the same circuitry from three polylines to two polylines. A double poly patterning mask layer 602 separates two polylines 607, 609 into four polyline segments. Thus, a PMOS device 614 having a different gate input can be located on a same polyline 609 (but different polyline segment) as the NMOS device 616 The polyline 607 includes an NMOS device 620 and a PMOS device 622 having a common gate contact 621. A PMOS device 624 is on a different segment of the polyline 607 and includes a gate contact 604 having the same input as the gate contact 606 of the NMOS device 616 on the other polyline 609. The gate contacts 604, 606 may be coupled in conductive (e.g., metal) layers, not shown.

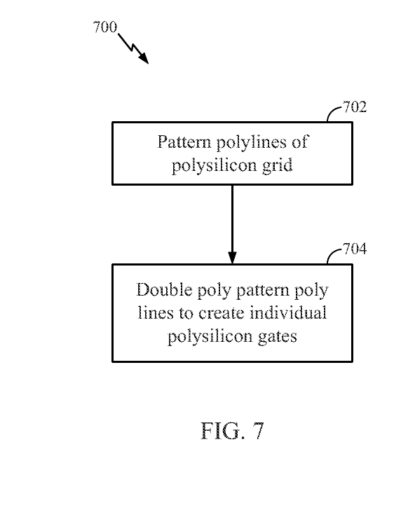

FIG. 7 is a flow chart illustrating an exemplary process 700 for fabricating a semiconductor according to an aspect of the present disclosure. In block 702, polylines are arranged on a polyline grid having a number of evenly spaced polylines. In block 704, double poly patterning cuts at least one polyline of the grid into a first polyline segment and a second polyline segment.

In accordance with various exemplary embodiments, a cell library specifying double polyline patterning can be used advantageously to specify the construction of devices having reduced area.

It should further be noted that the foregoing disclosed standard cell libraries can be configured into computer files having IC layout specifications according to an output format such as, Caltech Intermediate Format (CIF), Calma GDS interchange format (GDS II), Electronic Design Interchange Format (EDIF), Schematic User Environment (SUE), AutoCAD mechanical format (DXF), VHSIC hardware description language VHDL, hardware description language (Verilog), Cadence® circuit description language (CDL), EAGLE schematic capture interface format, ECAD schematic capture interface format, HPGL plotting language format, Postscript plotting language format, and the like. The specification files are stored on a computer readable media. These files are in turn provided to fabrication handlers who fabricate devices based on these files. The resulting products are semiconductor wafers that are then cut into semiconductor die and packaged into a semiconductor device. The packaged semiconductor devices are then employed in devices described below.

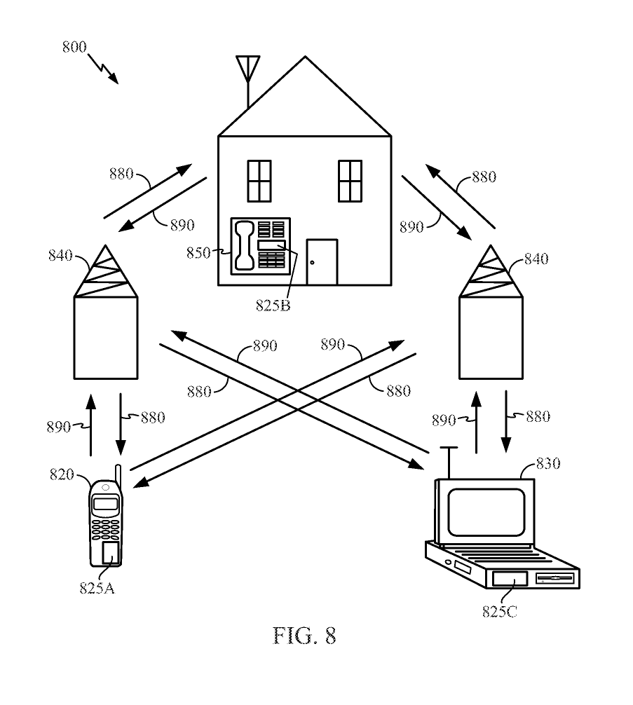

FIG. 8 is a block diagram showing an exemplary wireless communication system 800 in which an embodiment of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825C and 825B that include circuitry designed as described above. It will be recognized that any device containing an IC may also include the circuitry designed as described above, including the base stations, switching devices, and network equipment. FIG. 8 shows forward link signals 880 from the base station 840 to the remote units 820, 830, and 850 and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or any other device that stores or retrieves data or computer instructions, or any combination thereof. Although FIG. 8 illustrates remote units according to the teachings of the disclosure, the disclosure is not limited to these exemplary illustrated units. Embodiments of the disclosure may be suitably employed in any device which includes integrated circuits (ICs).

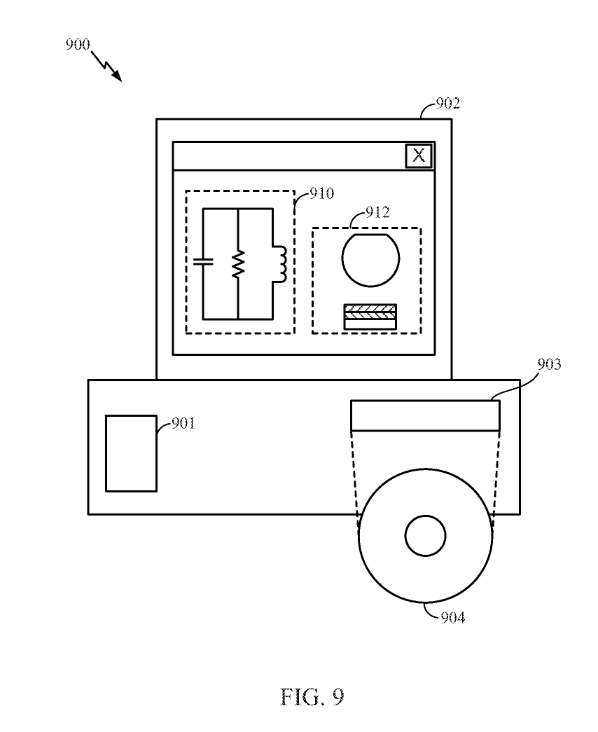

FIG. 9 is a block diagram illustrating a design workstation used for circuit, layout, and logic design of a semiconductor component, such as device disclosed above. A design workstation 900 includes a hard disk 901 containing operating system software, support files, and design software such as Cadence or OrCAD. The design workstation 900 also includes a display to facilitate design of a circuit 910 or a semiconductor component 912 such as an integrated circuit as discussed above. A storage medium 904 is provided for tangibly storing the circuit design 910 or the semiconductor component 912. The circuit design 910 or the semiconductor component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit design 910 or the semiconductor component 912 by decreasing the number of processes for designing semiconductor wafers.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although specific circuitry has been set forth, it will be appreciated by those skilled in the art that not all of the disclosed circuitry is required to practice the disclosure. Moreover, certain well known circuits have not been described, to maintain focus on the disclosure.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

While the foregoing disclosure shows illustrative embodiments of the disclosure, it should be noted that various changes and modifications could be made herein without departing from the scope of the disclosure as defined by the appended claims. The functions, steps and/or actions of the method claims in accordance with the embodiments of the disclosure described herein need not be performed in any particular order. Furthermore, although elements of the disclosure may be described or claimed in the singular, the plural is contemplated unless limitation to the singular is explicitly stated.

What is claimed is:

1. A semiconductor apparatus, comprising:
a semiconductor substrate;
a polysilicon layer patterned on the semiconductor substrate in a grid including a plurality of evenly spaced polysilicon gates, a first one of the polysilicon gates including a first polysilicon gate segment electrically separated from a second polysilicon gate segment, the first polysilicon gate segment and the second polysilicon gate segment configured to receive different input signals;
a first diffusion region in the semiconductor substrate, a portion of the first diffusion region being provided under the first polysilicon gate segment; and
a second diffusion area in the semiconductor substrate, a portion of the second diffusion area being provided under the second polysilicon gate segment.

2. The semiconductor apparatus of claim 1, in which the first polysilicon gate segment and the second polysilicon gate segment are separated as a result of double poly patterning.

3. The semiconductor apparatus of claim 2, further comprising:
a third diffusion area in the semiconductor substrate, a portion of the third diffusion area being provided under a second one of the polysilicon gates, which is adjacent to the first one of the polysilicon gates; and
a fourth diffusion area in the semiconductor substrate, a portion of the fourth diffusion area being provided under the second one of the polysilicon gates.

4. The semiconductor apparatus of claim 2, further comprising;
a third diffusion area in the semiconductor substrate, a portion of the third diffusion area being provided under a first polysilicon gate segment of a second one of the polysilicon gates, which is adjacent to the first one of the polysilicon gates; and
a fourth diffusion area in the semiconductor substrate, a portion of the fourth diffusion area being provided under a second polysilicon gate segment of the second one of the polysilicon gates, which is electrically separated from the first polysilicon gate segment of the second one of the polysilicon gates, at least one of the first polysilicon gate segment and the second polysilicon gate segment of the second one of the polysilicon gates being configured to receive a same input signals as a diagonally opposite polysilicon gate segment.

5. The semiconductor apparatus of claim 2, further comprising:
a third diffusion area in the semiconductor substrate, a portion of the third diffusion area being provided under the second polysilicon gate segment; and
a fourth diffusion area in the semiconductor substrate, a portion of the fourth diffusion area being provided under a third polysilicon gate segment, which is electrically separated from the first polysilicon gate segment and the second polysilicon gate segment, the third polysilicon gate segment being configured to receive a same input signal as the first polysilicon gate segment.

6. The semiconductor apparatus of claim 2, further comprising:
a third diffusion area in the semiconductor substrate, a portion of the third diffusion area being provided under a first polysilicon gate segment of a second one of the polysilicon gates, which is adjacent to the first one of the polysilicon gates;
a fourth diffusion area in the semiconductor substrate, a portion of the fourth diffusion area being provided under a second polysilicon gate segment of the second one of the polysilicon gates, which is electrically separated from the first polysilicon gate segment of the second one of the polysilicon gates; and
a fifth diffusion area in the semiconductor substrate, a portion of the fifth diffusion area being provided under the second polysilicon gate segment of the second one of the polysilicon gates.

7. The semiconductor apparatus of claim 1, integrated into at least one of a mobile phone, a set top box, a music player, a video player, an entertainment unit, a navigation device, a computer, a hand-held personal communication systems (PCS) unit, a portable data unit, and a fixed location data unit.

8. A method for fabricating a semiconductor apparatus, comprising:
using a polysilicon layer pattern above a plurality of diffusion regions in a semiconductor substrate to form a polysilicon grid; and
using a cut poly layer on at least one polyline of the polysilicon layer pattern to cut the at least one polyline into two individual polysilicon gates.

9. The method of claim 8, in which using the cut poly layer further comprises cutting two adjacent polylines into four individual polysilicon gates; and
configuring at least one pair of diagonally opposite individual polysilicon gates at the same potential.

10. The method of claim 9, further comprising:
integrating the semiconductor apparatus into at least one of a mobile phone, a set top box, a music player, a video player, an entertainment unit, a navigation device, a computer, a hand-held personal communication systems (PCS) unit, a portable data unit, and a fixed location data unit.

11. An apparatus for fabricating semiconductor devices, comprising:
means for using a polysilicon layer pattern above a plurality of diffusion regions in a semiconductor substrate to form a polysilicon grid; and
means for using a cut poly layer on at least one polyline of the polysilicon layer pattern to cut the at least one polyline into two individual polysilicon gates.

12. The apparatus of claim 11, further comprising:
means for cutting two adjacent polylines into four individual polysilicon gates; and
means for configuring at least one pair of diagonally opposite individual polysilicon gates at the same potential.

13. The apparatus of claim 11, integrated into at least one of a mobile phone, a set top box, a music player, a video player, an entertainment unit, a navigation device, a computer, a hand-held personal communication systems (PCS) unit, a portable data unit, and a fixed location data unit.

14. A method for fabricating a semiconductor apparatus, comprising steps of:
using a polysilicon layer pattern above a plurality of diffusion regions in a semiconductor substrate to form a polysilicon grid; and
using a cut poly layer on at least one polyline of the polysilicon layer pattern to cut the at least one polyline into two individual polysilicon gates.

15. The method of claim 14, in which using the cut poly layer further comprises cutting two adjacent polylines into four individual polysilicon gates; and
configuring at least one pair of diagonally opposite individual polysilicon gates at the same potential.

16. The method of claim 14, further comprising a step of:
integrating the semiconductor apparatus into at least one of a mobile phone, a set top box, a music player, a video player, an entertainment unit, a navigation device, a computer, a hand-held personal communication systems (PCS) unit, a portable data unit, and a fixed location data unit.
